(19) United States
(12) Patent Application Publication
(10) Pub. No.: US 2005/0082567 A1
(43) Pub. Date: Apr. 21, 2005

(54) Structure of a relaxed Si/Ge epitaxial layer and fabricating method thereof

(75) Inventors: Peng Shiu Chen, Hsinchu City (TW); Yang Tai Tseng, Hsinchu City (TW); Chee Wee Liu, Taipei City (TW)

Correspondence Address: BACON & THOMAS, PLLC, 625 SLATERS LANE, FOURTH FLOOR, ALEXANDRIA, VA, 22314, US

(73) Assignee: Industrial Technology Research Institute, Chutung (TW)

(21) Appl. No.: 10/847,913

(22) Filed: May 19, 2004

(30) Foreign Application Priority Data
Oct. 16, 2003 (TW) 092128744

(51) Int. Cl. H01L 31/072; H01L 21/302

(52) U.S. Cl. 257/190; 257/191; 438/936; 257/616; 438/752

(57) ABSTRACT

A structure of the relaxed SiGe epitaxial layer and a fabrication method comprises a Si substrate, a Si interfacial layer positioning on the substrate, a SiGe graded buffer layer positioning on the Si interfacial layer, and a uniform SiGe epitaxy layer positioning on the SiGe graded buffer layer. It uses a mesa structure and obtains a highly relaxed SiGe epitaxial layer with a low defect density of threading dislocations, a smooth surface. A strained Si can be formed on the strained relaxation layer. The strained Si, the strained Ge, the strained Si/Ge can apply to the high-speed planar electronic devices. By using a mesa structure, it can efficiently decrease the required growth time and cost in the conventional relaxed SiGe epitaxy layer.

### FIELD OF THE INVENTION

The present invention relates to a structure of the strained Si upon relaxed SiGe epitaxial layer and a fabrication method thereof. More particularly, it mainly means that a relaxed SiGe epitaxy structure and its fabricating method use a mesa structure. By using a mesa structure, it can reduce the density of threading dislocations with the appropriate heat treatment thereto obtain a fully relaxed SiGe epitaxial layer with a low defect density, a smooth surface. It can become a high quality start material for strained Si, strained Ge or III-V compound components.

### BACKGROUND OF THE INVENTION

Conventionally, the technique of relaxed SiGe epitaxial growth, such as a compositionally graded buffer, requires a long growth time. The larger surface roughness of the epitaxy layer can damage operational character of the planar electron devices, e.g. metal oxide semiconductors field electron transistor (MOSFET). Threading dislocations particularly become the source of carrier scattering, and therefore, decrease the carrier mobility. Sometime, the threading dislocations are the main reason of leakage current. According to the technique from E. A. Fitzgerald et al (U.S. Pat. No. 6,291,321), they provided a method with the graded layer to form a strained Si above relaxed SiGe epitaxial layer. This structure presently is the main stream of the relaxed SiGe epitaxial layer. However, it has a thicker thickness thereto takes long time to implement. More, the photolithography may have a difficult alignment and a high threading dislocation density (10^{5˜6} cm⁻²). Apart from this, Daniel Barasen et al disclosed (U.S. Pat. No. 5,221,413a) a method for making a semiconductor heterostructure of germanium-silicon alloy that has low threading dislocation density in the alloy layer. This invention is not good for the growth of the high quality relaxed SiGe epitaxial layer which is grown at high temperature. Moreover, E. A. Fitzgerald et al stated in U.S. Pat. No. 6,038,803 that a mis-orientation substrate can decrease the roughness. However, it is not compatible to the general ultra larger high system integral circuit(ULSI) processing.

In order to overcome the mentioned problems, the present invention is to provide a structure of the relaxation SiGe epitaxial layer and a fabrication method thereof with novelty. It can overcome the shortage of long growth in the conventional thick relaxed SiGe as well as keep the same relaxation, reduce the threading dislocation density and lower the surface roughness. The present inventors put many efforts on this invention based on long-term experience in product research, development, and marketing. Finally, the present invention is presented for overcoming the above problems.

### SUMMARY OF THE INVENTION

The main object of the present invention is to provide a method of fabricating the relaxed SiGe epitaxial layer and a structure of fabricating the same. The present invention uses a mesa structure in the relaxed SiGe uniform layer to obtain a low defect density, a smooth surface, and a virtual substrate with a highly relaxed SiGe epitaxial layer. The high quality strained Si, the strained Ge, and the strained SiGe alloy can be formed on the substrate and be applied to the high-speed planar electronic device like MOSFET. Further, it can decrease the growth time and cost of Si—Ge epitaxy layer. More, it can connect with III-V Compound elements to implement highly efficient optical performance.

Another object of the present invention is to provide a method of fabricating the relaxed SiGe epitaxial layer and a structure of fabricating the same, which can have the same relaxation as well as the prior art has. Similarly, it can decrease the roughness and threading dislocation density within the epitaxy layer in order to enhance the operational character of MOSFET related components.

In the SiGe epitaxial growth technique, the required relaxed SiGe epitaxial layer in the growth is formed on the Si substrate. As a result, the structure can be a virtual substrate to alternate original Si substrate for applying to the integration of high mobility transistors, MOS, III-V compound semiconductors, and strained Si start material. The relaxed SiGe epitaxial layer requires the characters of a high relaxation, a smooth surface of epitaxy layer, and a low defect density of threading dislocations.

The present invention uses a mesa structure to change configuration of the relaxed SiGe epitaxy layer. It can greatly shorten the required growth time of relaxed SiGe epitaxial layer. More, it has an obvious improvement on the surface roughness as well as on the poor electricity coming from threading dislocations. The SiGe epitaxial layer formed by the method of the present invention can provide as a virtual substrate. The strained Si, the strained Ge, and the strained SiGe can be formed on the substrate. The strained Si, the strained Ge, and the strained SiGe alloy form a highly efficient optical electronic integral circuit with various applications in MOSFETs-, and high-speed components with III-V Compound.

### BRIEF DESCRIPTION OF THE DRAWINGS

FIG. 1 is one preferred embodiment of the present invention showing a flow chart of the fabrication method for relaxed SiGe epitaxial layer with a mesa structure;

FIG. 2A is one of the preferred embodiments in the present invention showing a Si interfacial layer on a substrate;

FIG. 2B is one of the preferred embodiments in the present invention showing a Si—Ge graded buffer layer on the Si-buffer layer;

FIG. 2c is one of the preferred embodiments in the present invention showing a uniform Si—Ge epitaxy layer with a constant Ge content on the SiGe graded buffer layer.

### DETAILED DESCRIPTION OF THE PREFERRED EMBODIMENTS

There are just some of the features and advantages of the present invention. Many others will apparent by reference to the detailed description of the invention taken in combination with the accompanying drawings.

The purpose of the present invention is to overcome the conventional growth time of Si—Ge epitaxial layer. The present invention can obtain a smoother SiGe hetero-epitaxy layer thereto decrease threading dislocation density to under 10⁴ cm⁻² while in the same relaxation condition as the prior art has.

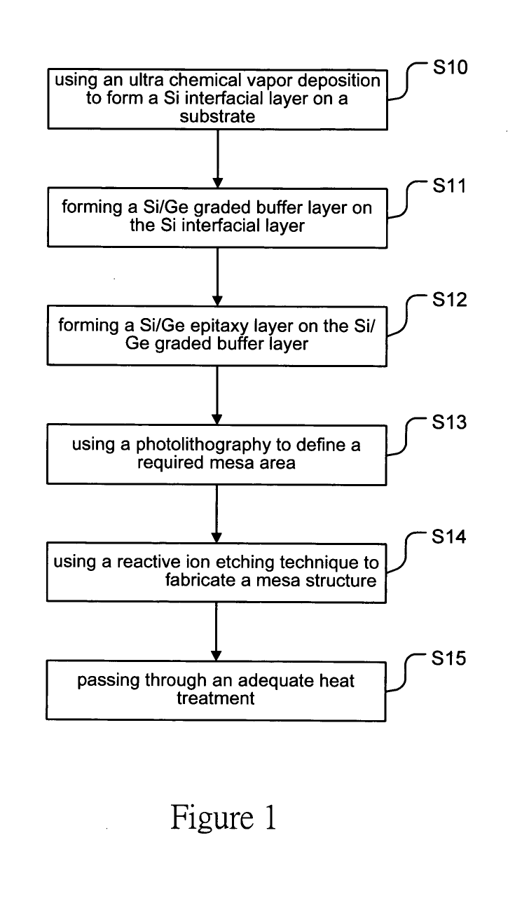

Please referring to FIG. 1, it is one preferred embodiment of the present invention showing a flow chart of a -relaxed SiGe epitaxial layer formed by a mesa structure. As shown in the figure, the fabrication method of a relaxed Si—Ge epitaxial layer mainly comprises the following steps, which are:
Step S10: Using an ultra high vacuum chemical vapor deposition to form a Si interfacial layer on a substrate;
Step S11: A SiGe graded buffer layer is formed on the Si interfacial layer;
Step S12: A uniform SiGe epitaxial layer with the constant Ge content is formed on the SiGe graded buffer layer;
Step S13: Using a photolithography to define a required mesa area;
Step S14: Using a reactive ion etching technique to fabricate a mesa structure; and
Step S15: Passing through an adequate heat treatment.

In the step S15, the heat treatment means that threading dislocations are away from the mesa structure and the misfit dislocations formed from Si/Ge graded buffer layer are restrained around the mesa structure. Similarly, the roughness is decreased to become smoothness.

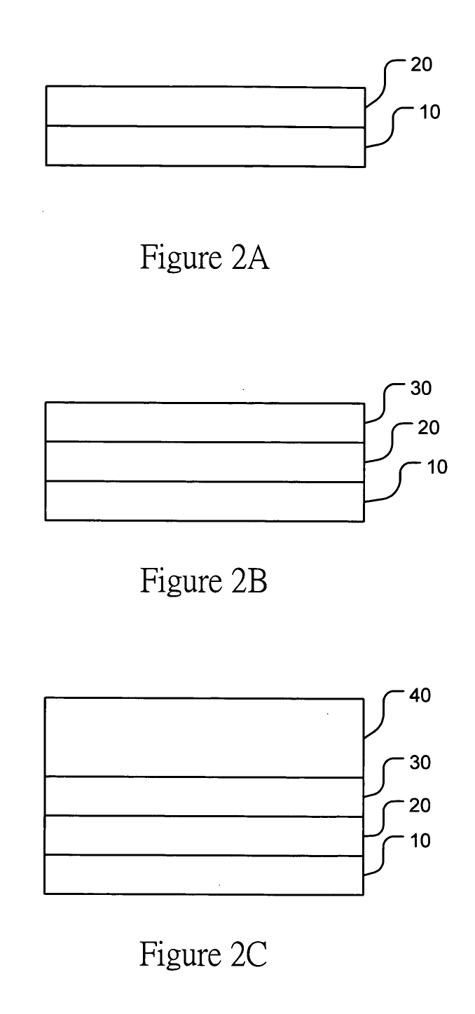

Please referring to FIG. 2A, FIG. 2B, and FIG. 2c. It is one of the preferred embodiments in the present invention showing a relaxed SiGe epitaxial layer with a mesa structure. As shown in the figure, it is a relaxed SiGe epitaxial layer structure in the present invention. It mainly comprises a substrate 10 with a Si interfacial layer 20 below, and a Si—Ge graded layer 30 is formed on the Si interfacial layer 20, and finally a uniform SiGe epitaxy layer 40 with the constant Ge content is formed on the SiGe graded layer 30.

The thickness of the Si/Ge graded buffer layer is 2 μm, and its Ge content is 0˜20%. The thickness of the Si/Ge epitaxy layer is 0.5˜2 μm. A strained Si, a strained Ge, and a strained SiGe are formed on the SiGe epitaxy layer for applying to different kinds of III-V compound components.

The present invention uses a mesa structure to change the configuration of the SiGe epitaxial layer and decrease threading dislocations. It, therefore, can greatly shorten the required growth time and cost of growing the relaxed SiGe epitaxial layer. More, it has an obvious improvement on the surface roughness. Since the threading dislocations cause poor electricity, it uses the mesa structure to assist threading dislocations away while processing heat treatment. This can obtain a SiGe epitaxy layer with a low defect density of threading dislocations, a smooth surface, and a complete relaxation. The SiGe epitaxy layer serves as a virtual substrate. The strained Si, the strained Ge, and the strained SiGe alloy can be formed on the substrate for applying to the high-speedplanar electronic devices. Further, it can efficiently decrease the required growth time and the cost of the conventional relaxed Si/Ge epitaxial layer.

In conclusion, the present invention meets novelty, improvement, and is applicable to the industry. It therefore meets the essential elements in patentability. There is no doubt that the present invention is legal to apply to the patent, and indeed we hope that this application can be granted as a patent.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims while which are to be accord with the broadest interpretation so as to encompass all such modifications and similar structures.

1. A relaxed SiGe epitaxy layer structure, comprising:
a substrate;
a Si interfacial layer positioning on the substrate;
a SiGe graded buffer layer positioning on the Si layer; and
a uniform compound SiGe epitaxial layer with the constant Ge content positioning on the SiGe graded buffer layer.

2. The structure according to claim 1, wherein the thickness of the SiGe buffer layer is 1˜2 μm.

3. The structure according to claim 1, wherein Ge content of the SiGe graded buffer layer is 0˜20%.

4. The structure according to claim 1, wherein the thickness of the SiGe epitaxy layer is 0.5˜1 μm.

5. The structure according to claim 1, wherein the strained Si can be formed on the SiGe epitaxy layer.

6. The structure according to claim 1, wherein the strained Ge can be formed on the SiGe epitaxy layer.

7. The structure according to claim 1, wherein the strained SiGe can be formed on the SiGe epitaxial layer.

8. A fabricating method of a relaxed Si/Ge epitaxial layer, comprising the steps of:
using an ultra high vacuum chemical vapor deposition to
form a Si interfacial layer on a substrate;
forming a SiGe graded buffer on the Si interfacial layer;
forming a SiGe epitaxy layer on the SiGe graded buffer layer;
using a photolithography to define a required mesa area;
using a reactive ion etching technique to fabricate a mesa structure; and
passing through an adequate heat treatment.

9. The structure according to claim 8, wherein the heat treatment means that threading dislocations are away from the mesa structure and the misfit dislocations formed from Si/Ge graded buffer layer are restrained around the mesa structure, and similarly, the roughness is decreased to become smoothness.
